(19) United States
(12) Patent Application Publication
(10) Pub. No.: US 2025/0141183 A1
(43) Pub. Date: May 1, 2025

(54) LASER CONTROLLER

(71) Applicant: BAE SYSTEMS Information and Electronic Systems Integration Inc., Nashua, NH (US)

(72) Inventors: Daniel P. Lacroix, Westford, MA (US); Zakary N. Burkley, Amherst, NH (US); Steven E. Turner, Nashua, NH (US); Mackenzie A. Van Camp, Lowell, MA (US); Shailendra Srinivas, Nashua (GB); Gary M. Madison, Waltham, MA (US); Brendan L. Metzner, Merrimack, NH (US)

(73) Assignee: BAE SYSTEMS Information and Electronic Systems Integration Inc., Nashua, NH (US)

(21) Appl. No.: 18/495,382

(22) Filed: Oct. 26, 2023

(51) Int. Cl. H01S 5/042; H01S 5/024

(52) U.S. Cl. CPC H01S 5/0427; H01S 5/02415

(57) ABSTRACT

Laser control circuitry is described. In one example, a laser controller integrated circuit (IC) includes first and second input ports, a sideband direct digital synthesizer (DDS) coupled to the first input port and configured to produce a modulation signal and a reference signal based on an input signal received via the first input port, the modulation signal and the reference signal having a same frequency. The laser controller IC further includes a Pound-Drever-Hall frequency-locking control loop coupled to the second input port and to the sideband DDS, and configured to produce a corrected DC bias current signal based on the reference signal and a measurement signal received via the second input port, and a thermal management circuit configured to produce at least one thermal control signal.

### FIELD OF DISCLOSURE

The present disclosure relates to laser systems and, more particularly, to control electronics for laser systems.

### BACKGROUND

Laser diodes are current driven and current sensitive semiconductor devices. Changes in the drive current produce corresponding changes in the wavelength and/or power output by the laser diode device. Any instability in the drive current, such as noise, drift, induced transients, etc., may affect the laser diode's performance characteristics, including its wavelength and output power. Accordingly, to safely drive a laser diode to produce a desired output involves the use of control electronics that are configured to generate a stable drive current and to control the temperature of the laser diode. Such control electronics are generally referred to as a laser diode driver or laser controller, and control the manner in which the laser diode is turned on and off and biased to produce a specific wavelength and output power level.

### SUMMARY

Aspects and embodiments are directed to techniques for providing a control system for laser diodes.

According to one embodiment, a laser controller integrated circuit (IC) comprises a digital programming interface, a first input port, a second input port, and a sideband direct digital synthesizer (DDS) coupled to the first input port and configured to produce a modulation signal and a reference signal based on an input signal received via the first input port, the modulation signal and the reference signal having a same frequency. The laser controller IC further comprises a Pound-Drever-Hall frequency-locking control loop coupled to the second input port and to the sideband DDS, and configured to produce a corrected DC bias current signal based on the reference signal and a measurement signal received via the second input port. The laser controller IC further comprises a thermal management circuit configured to produce at least one thermal control signal.

Further embodiments include a laser controller incorporating the laser controller IC, and a laser system including a laser diode and the laser controller.

Still other aspects, embodiments, and advantages of these example aspects and embodiments are discussed in detail below. Embodiments disclosed herein may be combined with other embodiments in any manner consistent with at least one of the principles disclosed herein, and references to “an embodiment,” “some embodiments,” “an alternate embodiment,” “various embodiments,” “one embodiment” or the like are not necessarily mutually exclusive and are intended to indicate that a particular feature, structure, or characteristic described may be included in at least one embodiment. The appearances of such terms herein are not necessarily all referring to the same embodiment.

### BRIEF DESCRIPTION OF THE DRAWINGS

In the figures:

FIG. 1 is a block diagram illustrating an example of laser system according to aspects of the present disclosure;

FIG. 2 is a block diagram illustrating an example of certain components of the laser system of FIG. 1, according to aspects of the present disclosure;

FIG. 3 is a block diagram of one example of certain components a laser system, including an integrated laser controller according to aspects of the present disclosure;

FIG. 4 is a schematic diagram of one example a tuning circuitry for a laser diode according to aspects of the present disclosure;

FIG. 5 is a schematic diagram of some circuitry of the laser controller of FIG. 3, including an example of a Pound-Drever-Hall frequency locking control loop according to aspects of the present disclosure;

FIG. 6 is a circuit diagram of one example of a loop filter than can be used in the Pound-Drever-Hall frequency locking control loop of FIG. 5, according to aspects of the present disclosure;

FIG. 7 is a graph showing one example of a transfer function for the loop filter of FIG. 6, according to aspects of the present disclosure;

FIG. 8 is a block diagram showing an example of temperature control circuitry for the laser system of FIG. 1, according to aspects of the present disclosure;

FIG. 9 is a block diagram showing one example of thermal control and management circuitry that can be used in the laser system of FIG. 1, according to aspects of the present disclosure;

FIG. 10 is a circuit diagram of one example of a temperature sensor conditioning circuit that may be implemented in the thermal control and management circuitry according to aspects of the present disclosure;

FIG. 11 is a circuit diagram of one example of a PID controller that can be implemented in the thermal control and management circuitry of FIG. 9 according to aspects of the present disclosure; and

FIG. 12 is a perspective view illustrating one example of a housing containing a laser system according to aspects of the present disclosure.

Although the following detailed description will proceed with reference being made to illustrative embodiments, many alternatives, modifications, and variations thereof will be apparent in light of this disclosure.

### DETAILED DESCRIPTION

Techniques disclosed herein provide a miniaturized, integrated laser diode control and driver system. According to one embodiment, a laser controller integrated circuit (IC) for a laser diode system comprises first and second input ports, a sideband direct digital synthesizer coupled to the first input port and configured to produce a modulation signal based on an input signal received via the first input port, and a Pound-Drever-Hall (PDH) frequency-locking control loop coupled to the second input port and to the sideband direct digital synthesizer. The modulation signal may be used to modulate sidebands of a laser signal output by the laser diode. The PDH frequency-locking control loop can be configured to produce a corrected DC bias current signal for the laser diode based on the modulation signal and a measurement signal received via the second input port, the measurement signal being representative of at least one sideband of the laser signal. The laser controller IC further comprises a thermal management circuit configured to produce at least one thermal control signal for tuning a temperature of the laser diode. The laser controller IC may further comprise a digital programming interface. In some examples, the digital programming interface includes a serial interface, such as an I2C interface, and one or more configuration registers in which programming values for various components and operating parameters of the laser controller IC can be stored. These and other features of laser diode control and driver system are described in more detail below.

### General Overview

As described above, a laser diode driver is used to control operating parameters of a laser diode system, such as the wavelength and output power of the laser diode. Ideally, the laser diode driver provides a stable drive current, which in some instances can have a high current value. Rack mount laser controllers and drivers, while potentially offering desirable performance characteristics, are large and expensive, making them unsuitable for many applications. Accordingly, aspects and embodiments are directed to techniques providing a low noise integrated circuit solution for a laser controller and driver that can replace rack mount systems.

Certain embodiments are directed to providing a high current, low noise laser that is temperature stabilized and actively frequency stabilized to a high-finesse micro-resonator through the use of offset Pound Drever Hall (PDH) locking. This may involve providing: 1) a high current, low noise temperature controller and thermoelectric cooler (TEC); 2) a high current, low noise laser driver with direct modulation capabilities; 3) a control loop to provide PDH locking; and 4) tunable sideband modulation over a specified frequency range. As described in more detail below, embodiments disclosed herein provide a complete laser bias, temperature, and frequency control system having the above features and capabilities within a compact form factor.

According to certain embodiments, techniques are disclosed for partitioning various circuit blocks of the laser control system, such that components having high current or power requirements, and/or high associated coupled transient noise, are implemented off-chip, while all control components can be integrated into a low power, compact integrated circuit (IC). In examples, to achieve a compact, integrated solution, control functionality is implemented using digitally controlled servo loops for frequency stabilization and noise control, direct digital synthesis for modulation, and digital control of the laser bias current. The use of digital electronics, rather than analog systems, may provide higher accuracy control while consuming less power and producing less noise.

For example, according to certain embodiments, there is provided a digitally controlled laser driver with direct modulation capability for controlling the frequency (wavelength) of the output laser beam. A configurable PDH frequency-locking servo loop can be used for precise frequency tuning. Certain examples also include the ability to generate programmable sideband modulation tones via a sideband direct digital synthesizer (DDS), as described further below. In some examples, tunable sideband modulation is provided over a frequency range of about 0 to 100 Megahertz (MHz). An additional servo loop may be provided for relative intensity noise (RIN) suppression. Certain examples further include integrated TEC controller front-end thermistor signal processing circuitry configured to communicate with external high-current TEC driver circuitry, as described in more detail below. The control circuitry, and therefore various parameters of the laser, may be fully configurable through a communications interface, such as an I2C or SPI serial interface, for example. The use of these techniques allows a complete laser controller to be made far smaller than rack mount controllers (e.g., in an integrated circuit, rather than using several rack mount modules), while providing precision control of the laser performance and characteristics.

### Example System Architecture

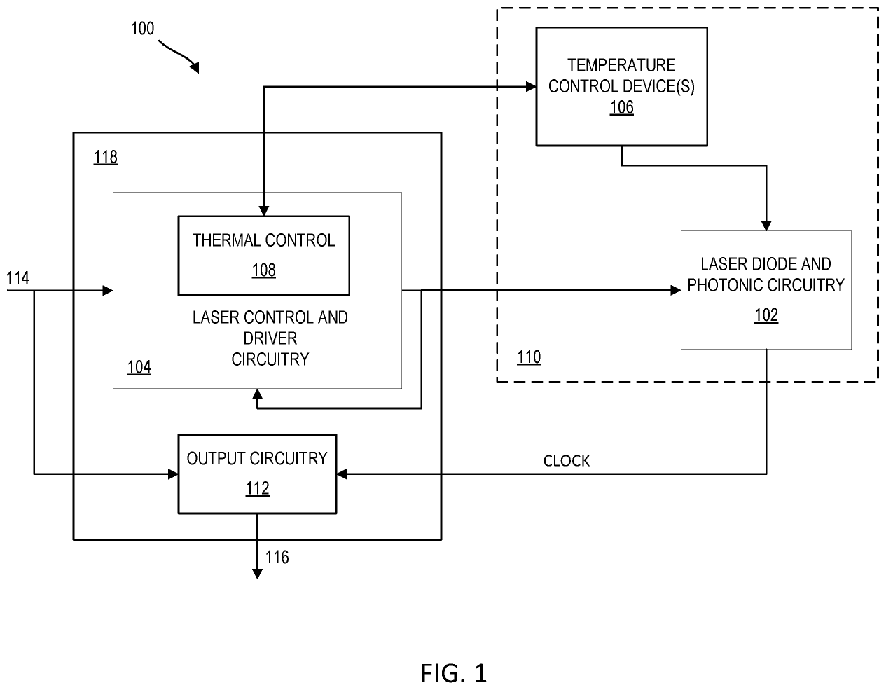

FIG. 1 is a block diagram of an example laser system 100 in accordance with aspects of the present disclosure. The laser system 100 includes a laser sub-system 102 that includes a laser diode and photonic circuitry. The laser system 100 further includes laser control and driver circuitry 104. In some examples, control functionality associated with the laser control and driver circuitry 104 may be implemented in a single integrated circuit, as described further below. The laser system 100 further includes one or more temperature control devices 106 for controlling a temperature of the laser diode during operation. The temperature control device(s) 106 may include one or more TECs and/or heaters. Accordingly, the laser control and driver circuitry 104 may include thermal control circuitry 108 coupled to the temperature control device(s) 106, as shown in FIG. 1. In some examples, the photonic circuitry of the laser sub-system 102 and the temperature control device(s) 106 may be implemented on a common/shared integrated circuit board or photonic substrate 110, such as a silicon nitride substrate, for example.

The laser system 100 may further include output circuitry 112. In some examples, the output circuitry 112 receives a high speed/frequency clock signal from the laser sub-system 102 along with a low speed/frequency input signal 114 to provide a conditioned output laser beam 116. The input signal 114 may also be used by one or more elements of the laser control and driver circuitry 104, as described further below. In some examples, the laser sub-system 102 provides a 50 Gigahertz (GHz) clock signal, the input signal 114 is a 100 MHz signal, and the output circuitry provides a tunable output laser beam 116 having a frequency that is tunable over a range of 1-40 GHz. In some examples, the laser control and driver circuitry 104 and the output circuitry 112, or at least some components thereof, are implemented on a common electronics substrate 118.

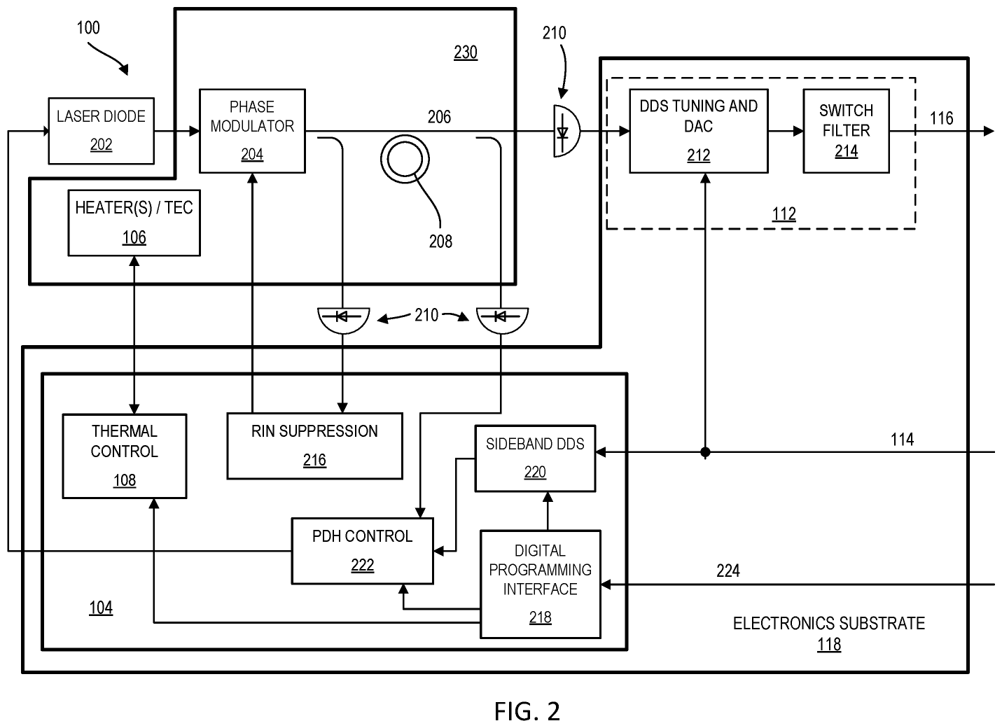

Referring to FIG. 2, there is illustrated a more detailed block diagram of one example implementation of the laser system 100. As shown, the laser system 100 includes a laser diode 202 coupled to a photonic integrated circuit (PIC) 230, the combination of which corresponds to the laser sub-system 102 of FIG. 1 in some examples. The PIC 230 may be implemented on a silicon nitride substrate, for example. The PIC 230 may include a phase modulator 204, one or more micro-resonators 208, and the temperature control device(s) 106. In one example, the micro-resonator 208 is a magnesium fluoride (MgF₂) resonator. The laser diode 202 produces an output beam that is provided to the phase modulator 204 which modulates the output beam from the laser diode to produce a high frequency clock signal 206 (corresponding to the clock signal shown in FIG. 1). In some examples, the clock signal 206 is a fixed 50 GHz clock signal; however, in other examples, a different clock frequency can be selected. The clock signal 206 may be sampled using photodetectors 210 to provide measurements of the clock signal 206 to various control components, as described further below.

In some examples, the phase modulator 204 is implemented as a Mach-Zender interferometer (MZI); however, in other examples, another type of phase modulator may be used. As noted above, the temperature control device(s) 106 may include one or more heaters and/or thermoelectric coolers (TECs), for example. In some examples, the TEC can also function as a heater, depending on the polarity of its drive current, as described further below.

According to certain examples, the output circuitry 112 includes DDS tuning and digital-to-analog converter (DAC) circuitry 212 along with a switch filter 214. The DDS tuning and DAC circuitry 212 receives the clock signal 206 and the input signal 114 and provides tuning to control the frequency of the tunable output beam 116. As described above, in certain examples in which the clock signal 206 is a fixed 50 GHz clock, the output beam 116 is tunable in frequency over a range of 1-40 GHz. The switch filter 214 may implement various filtering to condition the output beam 116 and switching to control the frequency of the output beam 116.

The laser control and driver circuitry 104 provides control functionality to control operating parameters of the laser diode 202, such as the frequency of the clock signal 206 and the output power level, and also provides temperature stabilization control for the laser diode 202. As described further below, in certain examples, the laser control and driver circuitry 104 provides temperature control, noise suppression, bias control for the laser diode 202, and sideband tuning for the output beam from the laser diode 202. The laser control and driver circuitry 104 may further provide active frequency stabilization for the laser diode 202. In particular, as described above, in certain examples, the output from the laser diode 202 is frequency stabilized to the high-finesse micro-resonator 208 through the use of offset Pound-Drever-Hall (PDH) locking. As shown in FIG. 2, in certain examples, the laser control and driver circuitry 104 includes a relative intensity noise (RIN) suppression component 216, thermal control circuitry 108, a PDH control loop 222, and a sideband direct digital synthesizer (DDS) 220. Examples of these components are described further below with continuing reference to FIG. 2.

In some examples, the laser control and driver circuitry further comprises a digital programming interface 218 to allow for digital tuning and configuration of various components of the system, including the PDH control loop 222, the sideband DDS 220, and the thermal control circuitry 108. The digital programming interface 218 receives control information, in the form of one or more digital configuration signals 224 from one or more external sources, and in turn provides control signals to the PDH control loop 222, the sideband DDS 220, and the thermal control circuitry 108 to control various parameters of each component. For example, for the sideband DDS 220, parameters such as the frequency (e.g., set by a DDS frequency control word) and modulation depth can be controlled/specified via the digital programming interface 218. For the PDH control loop, several parameters, such as the gain of various stages, sidetone phase shift, DC offset, etc., can be controlled/specified via the digital programming interface 218. Similarly, characteristics such as the gain and temperature settings of the thermal control circuitry 108 can be controlled/specified via the digital programming interface 218. These and other examples are described further below.

The laser control and driver circuitry 104 implements a variety of different functions as described above, and therefore may include circuit blocks with very different characteristics and requirements. For example, certain components may operate with much higher current and/or voltage levels than other components. In addition, certain components may have high transient levels that are incompatible with some low voltage semiconductor technologies. To achieve a complete integrated control solution, techniques disclosed herein include partitioning certain circuit blocks into external circuit boards, substrates, and/or chipsets, while packaging the remaining components into a dedicated, compact laser controller integrated circuit (IC). For example, certain circuit blocks having high voltage and/or current requirements, or having high transients and/or associated noise levels, can be implemented as external components, thereby allowing the laser controller IC to be implemented using low voltage semiconductor processing, such as 3.3 volt (V) bipolar CMOS (BiCMOS) processing, for example.

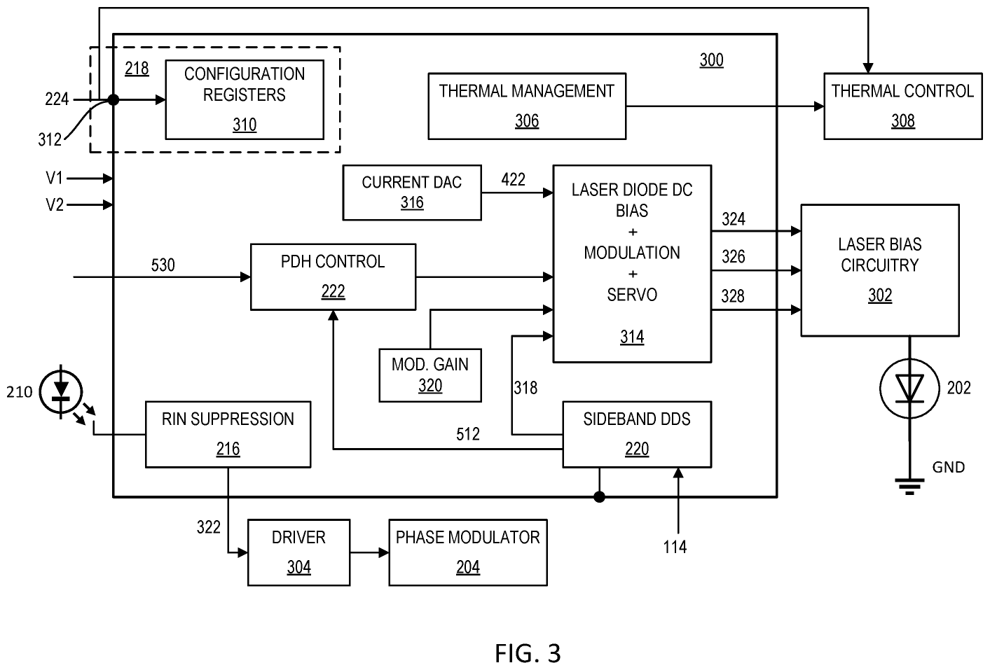

FIG. 3 is a block diagram of one example of a laser system, in which certain laser control functionality of the laser control and driver circuitry 104 is implemented as a laser controller IC 300 and other circuit blocks are partitioned into external components. In the illustrated example, laser bias circuitry 302 and driver circuitry 304 for the phase modulator 204 are implemented external to the laser controller IC 300. In addition, the thermal control circuitry 108 of FIG. 2 is partitioned into on-chip thermal management circuitry 306 and external thermal control circuitry 308. In some examples, the thermal control circuitry 308 may include some or all of the temperature control device(s) 106 for the laser diode 202. This partitioning allows “front-end” control for thermal stabilization of the laser diode 202 and PIC 230 to be integrated into the laser controller IC 300, while higher power components are implemented off-chip, as described further below.

For example, the laser bias circuitry 302 may include one or more power transistors, such one or more PNP power transistors, for example, capable of handling relatively high current (e.g., 0.6-1.2 Amperes (A) in some examples). The driver circuitry 304 may include a level shifter, one or more power transistors, and/or other components that also operate using relatively high current and higher voltages than the control components integrated in the laser controller IC 300. For example, the laser bias circuitry 302 may operate using a 4-5 V supply voltage, and the driver circuitry 304 may provide an output drive voltage in a range of about 5-24 V in some examples. In contrast, as discussed above, the laser controller 300 may be implemented using 3.3 V BiCMOS processing, which may be achieved, in part, by partitioning certain higher-power components, such as those associated with the laser bias circuitry 302 and/or driver circuitry 304, into one or more external packages, as shown in FIG. 3

According to certain examples, the laser controller IC 300 provides all control functions for the laser diode 202, including DC bias control, sideband tuning, frequency stabilization, and temperature control. As described above, the laser controller IC 300 may be fully configurable and programmable via the digital programming interface 218. In the example of FIG. 3, the digital programming interface 218 includes one or more configuration registers 310 coupled to a configuration interface 312. The configuration interface 312 may be an I2C serial configuration interface, for example, although other interface technologies can be used. Through configuration signals 224 received from one or more external sources via the configuration interface 312, the configuration register(s) 310 can be programmed/updated to set desired characteristics or parameters for controlling the laser diode 202, such as a desired frequency, DC bias current level, sideband characteristics, operating temperature range, and/or any other control parameters as may be used in various applications. Further, various parameters and characteristics of components of the laser controller IC 300, such as the PDH control loop 222, the sideband DDS 220, and the thermal management circuitry 306, for example, can be set through configuration signals 224 received via the digital programming interface 218, as described above.

The laser controller IC 300 may be coupled to one or more supply voltages V1, V2 that supply operating power for the components of the laser controller 300. In one example, V1=3.3V and V2=1.2 V; however, in other examples, other voltage levels may be used and/or the laser controller IC 300 may be coupled to more than two or to only one supply voltage.

As discussed above, in certain examples, the laser control and driver circuitry 104 is configured to implement RIN suppression to reduce phase noise in the clock signal 206. Accordingly, in certain examples, the laser controller IC 300 includes the RIN suppression component 216. The RIN suppression component 216 may receive one or more samples of the clock signal 206 via one or more photodiodes 210. In some examples, the RIN suppression component receives two samples of the clock signal 206 via two photodiodes 210 and implements an intensity modulator in a closed loop servo system based on the two samples to generate a corrected signal 322 that is fed to the off-chip driver 304 for the phase modulator 204. RIN suppression may advantageously reduce short-term noise in the clock signal 206 and improve performance of the laser system 100.

Still referring to FIG. 3, in certain examples, the laser controller IC 300 includes a current sum circuit 314 that provides three output signals, namely the specified DC bias current 324 for the laser diode, a frequency control output 326, also referred to as a “servo” current since the laser frequency is stabilized using a PDH servo control loop 222, and a sideband modulation current 328. The servo current 326 and the sideband modulation current 328 may be superimposed on the DC bias current 324, such that the three outputs shown in FIG. 3 are combined into a single current signal sent to the laser diode 202. As described further below, the sideband modulation current 328 may be produced by the sideband DDS 220 and used to provide tunable sideband modulation of the laser diode 202 over a specified frequency range. The DC bias current 324 and servo current 326 are used to drive the laser bias circuitry 302 to provide the laser diode 202 with a stable, low noise DC bias current. In certain examples, the DC bias current is in a range of 0.6 A-1.2 A. In some examples, the DC bias current value is set through a configuration signal 224 received via the digital programming interface 218.

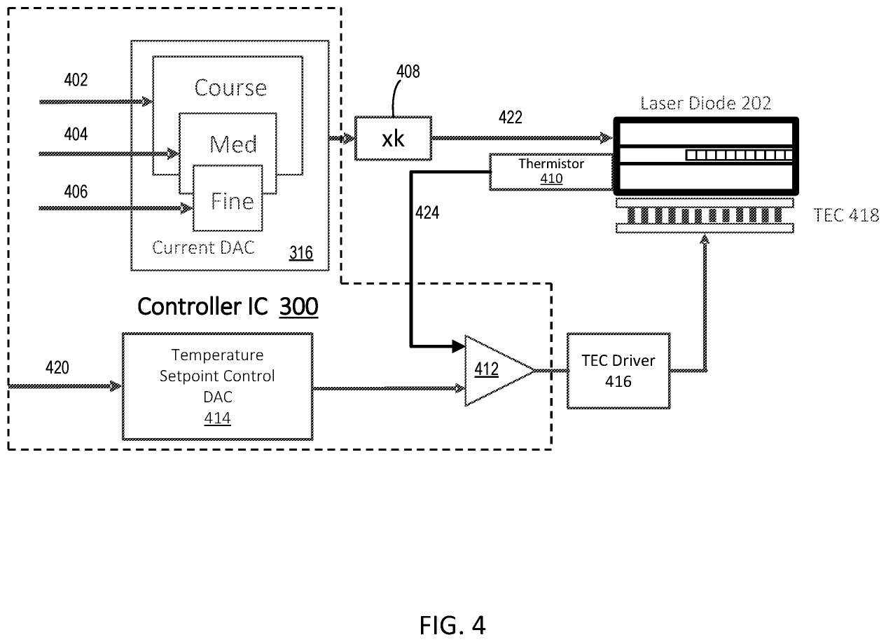

Frequency tuning of the laser diode 202 may be established through a combination of temperature control and the bias current. FIG. 4 illustrates an example of componentry of the laser controller IC 300 that can be used for frequency tuning of the laser diode 202. It will be appreciated that, for simplicity, FIG. 4 does not illustrate other components and circuitry that may be part of the laser controller IC 300.

Referring to FIGS. 2-4, the micro-resonator 208 may establish one or more high-Q resonances. The free spectral range of the micro-resonator 208 ideally determines the spacing between resonances; however, in many circumstances, the actual resonance modes can be more complex. Accordingly, a frequency scan can be performed to identify useful resonances for locking the laser diode 202 to stabilize the clock frequency. Traditionally, an analog ramp of the DC bias current can be used to perform this frequency scan. In contrast, according to certain examples, the frequency scan is performed digitally using a current DAC 316. As described above, the use of digital electronics for various control features allows the laser controller IC 300 to be implemented in a low voltage, small form-factor integrated package.

According to certain examples, the current DAC 316 operates as a bias current controller that can be configured to provide course, medium (med), and fine tuning of the bias current 324 for the laser diode 202. Accordingly, the current DAC 316 may receive three control inputs 402, 404, 406, as shown in FIG. 4. In one example, each of the three control inputs is an 8-bit signal; however, in other examples, the control inputs may comprise another number of bits and the three inputs need not have the same number of bits. Each of the control inputs may be provided via the digital programming interface 218. Based on the control input 402, the current DAC 316 may set a course DC bias current 324 for the laser diode 202. As described above, in one example, this DC bias current 324 may be in a range of 0.6 A to 1.2 A. In some examples, to achieve this relatively high current level, the output from the current DAC 316 may be level shifted by a current multiplier 408. For example, the current multiplier 408 may multiply the amplitude of the current by a factor of k. In one example, k=100; however, other multiplication factors may be used. In some examples, the current multiplier 408 may be positioned between the current DAC 316 and the current sum circuit 314 (not shown in FIG. 4). Thus, the current DAC 316 produces a DC bias current signal 422 that is provided to the current sum circuit 314.

After the course DC bias current range has been set, the current DAC 316 can be controlled, via the control inputs 404 and 406, to sweep the DC bias current 324 over a set range so as to scan the laser frequency over a certain range to find resonances of interest, as described above. The current DAC 316 may be scanned over a programmable range and at a programmable scan rate. For example, to perform a frequency scan over a range of 30-300 MHz may correspond to tuning the DC bias current over a range of about 0.2-2 mA. The DC bias current can be controlled over this range by programming the current DAC 316 using the control inputs 404, 406. Precise and programmable digital control allows the frequency scan to be performed with very fine precision over a desired scan range and without the need for conventional analog control. For example, the current DAC 316 can be configured to provide fine current resolution (e.g., in a range of approximately 0.5-1 μA based on the control input 406) equivalent to a frequency step of less than 100 kHz. In certain examples, the current DAC 316 can be programmed for a particular scan range and/or step frequency via the configuration registers 310 and configuration interface 312.

According to certain examples, temperature control can be used to sweep the laser frequency over twice the free spectral range (which may be equivalent to a range of approximately 80 GHz in some examples) to within a specified margin of an identified resonance frequency. In some examples, the margin is 300 MHZ, corresponding to the frequency scan range performed using the current DAC 316 as described above. Still referring to FIG. 4, in some examples, a thermistor 410 is coupled to the laser diode 202 and to a comparator 412 on the laser controller IC 300. The thermistor 410 may be used for temperature sensing, as described further below. A desired temperature, selected to tune the laser diode frequency to a particular frequency within the scan/sweep range, for example, may be set using a temperature setpoint control DAC 414. The temperature setpoint control DAC 414 provides a temperature setpoint signal, expressed as a DC current value, to one input of the comparator 412. The other input of the comparator 412 receives a thermistor sensing signal 424, as shown in FIG. 4. The comparator 412 compares the signals received at its two inputs and provides an output signal to a TEC driver 416. The TEC driver 416 is coupled to a TEC 418 that is coupled to the laser diode 202 and adjusts a temperature of the laser diode 202. Thus, the frequency of the laser diode 202 can be tuned by driving the TEC 418, via the TEC driver 416, to adjust the temperature of the laser diode 202. The TEC driver 416 may be implemented as part of the thermal control circuitry 308. The comparator 412 and the temperature setpoint control DAC 414 may be implemented as part of the thermal management circuitry 306 on the laser controller IC 300. The temperature setpoint may be specified by a temperature control signal 420 that may be input to the temperature setpoint control DAC 414 via the digital programming interface 218, for example. Further aspects of temperature control of the laser diode 202 and the PIC 230 are described below with reference to FIGS. 3 and 8-11.

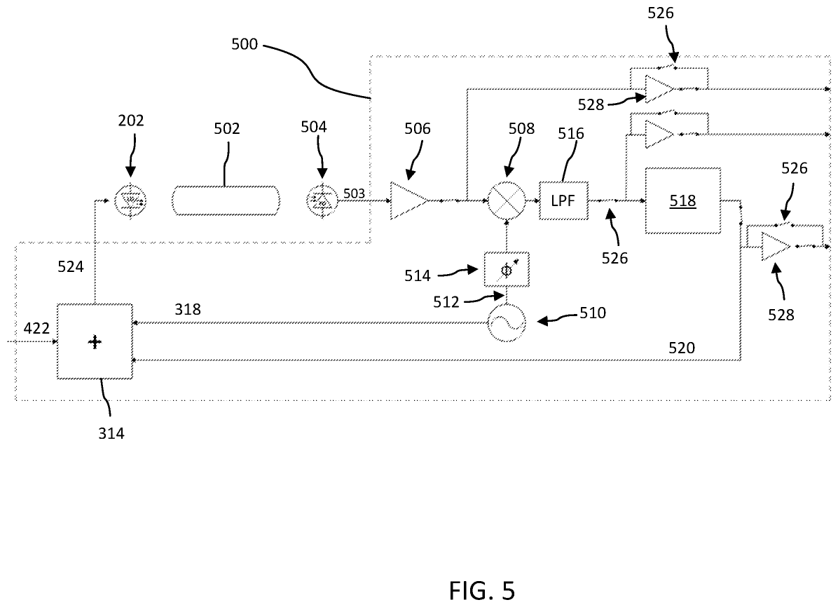

As described above, once a resonance frequency of the micro-resonator 208 has been selected, the PDH frequency locking control loop 222 may be used to stabilize the frequency of the laser diode 202. Referring to FIG. 5, there is illustrated circuitry 500 including one example of components of the PDH control loop 222 according to certain aspects. The PDH technique allows for stabilizing the frequency of light emitted by the laser diode 202 by locking on to a stable cavity, such as the micro-resonator 208. Frequency stabilization may be needed for high precision laser applications because all lasers demonstrate frequency wander at some level. This instability may be due to temperature variations, mechanical imperfections, and laser gain dynamics (which change laser cavity lengths), laser driver current and voltage fluctuations, atomic transition widths, and many other factors. PDH locking addresses the problem of frequency wander by actively tuning the laser diode 202 to match the resonance condition of a stable reference cavity, in this case, the micro-resonator 208.

In the example of FIG. 5, the PDH control loop 222 includes a transimpedance amplifier 506, a down-conversion mixer 508, a low-pass filter 516, and a loop filter 518. In some examples, phase-modulated light output from the laser diode 202, which includes a carrier frequency and two sidebands, is directed into a photonic channel 502, which includes the micro-resonator 208. Light emanating from the thru port of the micro-resonator 208 is measured using a high speed photodetector 504. The signal includes the two unaltered sidebands along with a phase-shifted carrier component. The measurement signal 530 from the photodetector 504 is provided to the transimpedance amplifier (TIA) 506. In some examples, the measurement signal 530 from the photodetector 504 is a current signal that corresponds to a 10-100 MHz sideband signal from the micro-resonator 208. Accordingly, the TIA 506 acts as an interface with the photodetector 506 and produces a voltage output to drive the down-conversion mixer 508. In some examples, the input signal range for the TIA 506 is approximately 1 μA-1 mA peak. In one example, the TIA 506 has a bandwidth of 300 MHZ, for an input signal in a frequency range of 10-100 MHZ, and a gain of approximately 5V/μA. In some examples, since the phase of the measurement signal 530 from the photodetector 504 relative to an original sideband modulation of the laser diode output is of interest, the TIA 506 is implemented as a limiting amplifier driving into the mixer 508 that also receives a signal representative of the original sideband modulation.

In examples, a local oscillator (LO) 510 provides a reference signal 512 that is in phase with the original sideband modulation of the output beam from the laser diode 202 and is fed to the mixer 508. As described above, in certain examples, direct digital synthesis can be used to generate programmable sideband modulation tones for the laser diode 202. Accordingly, in some examples, the local oscillator 510 is implemented as part of the sideband DDS 220.

Referring to FIGS. 3 and 5, based on the low-frequency input signal 114 and digital control signals received via the digital programming interface 218, the sideband DDS 220 produces two output signals 318, 512. Both signals 318, 512 have the same frequency that is set by a DDS frequency control word received via the digital programming interface 218. The first signal output from the sideband DDS 220 is a modulation signal 318 that is provided, via the current sum circuit 314, to the laser diode as the modulation current 328. In one example, the modulation signal 318 is filtered to be a sinusoidal signal). This modulation signal 318 is used to provide tunable sideband modulation of the laser diode 202 over a specified frequency range, as described above. In some examples, a voltage-to-current converter (not shown) is used to convert the sinusoidal modulation signal 318 output from the sideband DDS 220 to a current (the modulation current 328) that can be added to the DC bias current 324 in the current sum circuit 314. In some examples, the modulation current 328 is much smaller than the DC bias current, and therefore rides on top of the DC bias current 324. Thus, the modulation signal 318 output from the sideband DDS 220 is sent to the laser diode as a current modulation. The modulation depth may be set through a control signal received via the digital programming interface 218. In some examples, a modulation gain DAC 320 provides digital control of a gain of the sideband tones. The gain may be set via the digital programming interface 218.

The second signal output by the sideband DDS 220 is the reference signal 512 that is provided to the mixer 508. In some examples, the reference signal 512 is passed via a phase shifter 514 to tune the phase of the reference signal 512. In some examples, the resolution of the phase shifter 514, and the phase shift value, can be set by control signals received via the digital programming interface 218. In one example, the reference signal 512 is a 1.2V square wave having a frequency in a range of about 10-100 MHZ. The reference signal 512 is mixed with the output from the TIA 506 in the mixer 508. Thus, because the reference signal 512 is produced by the same local oscillator 510 as the modulation signal 318 that is used to control sideband modulation of the laser diode 202, the reference signal 512 is in phase with the original sideband modulation of the output beam from the laser diode 202, as noted above.

Still referring to FIGS. 3 and 5, the output from the mixer 508 is filtered by the low pass filter 516 and then provided to the loop filter 518. In some examples, the 3 dB point of the low-pass filter 516 can be adjusted by a control signal received via the digital programming interface 218. After filtering, the resulting electronic signal 520 gives a measure of how far the laser carrier is off resonance with the micro-resonator 208 and may be used as feedback for active frequency stabilization of the laser diode 202. In one example, the electronic feedback/error signal 520 is fed to the current sum circuit 314, which also receives the laser DC bias current 422 and the modulation signal 318 from the local oscillator 510, as described above, to provide the servo current 326. The servo current 326, representing the error signal 520, can be added to the DC bias current 324 in the same manner as described above for the modulation signal 318. Thus, the output 524 from the current sum circuit 314 includes the DC bias current signal 324, with both the modulation current 328 and the servo current 326 corresponding to the error signal 520 superimposed on the DC bias current signal 324. The servo current 526 “corrects” the DC bias current signal 324 provided to the laser diode 202 to stabilize the frequency of the clock signal 206 and keep the laser diode 202 locked on resonance with the micro-resonator 208.

In some examples, combinations of switches 526 and buffer amplifiers 528 may provide various monitoring and/or override points within the PDH control loop 222, as shown in FIG. 5. The switches can be controlled (e.g., caused to be opened or closed) by control signals received via the digital programming interface 218.

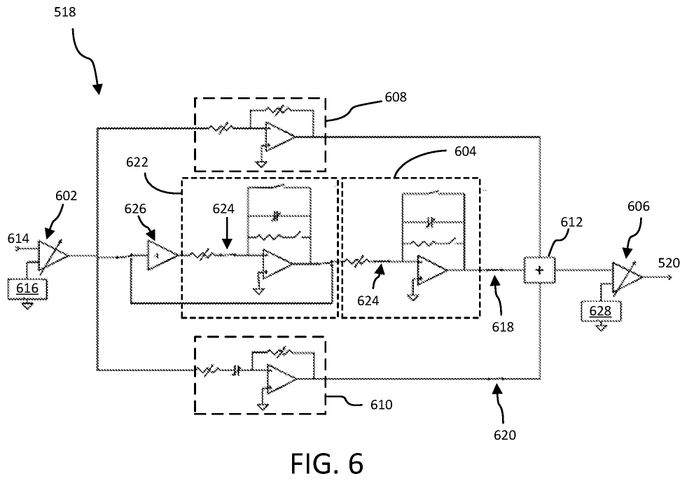

FIG. 6 is a circuit diagram of one example of the loop filter 518 that can be used in the PDH control loop 222. In this example, the loop filter 518 is a configurable proportional-integral-derivative (PID) filter. In the illustrated example, the loop filter 518 includes an input variable gain stage 602 to provide front-end gain, an integrator 604, and an output variable gain stage 606 to provide output gain. A proportional gain stage 608 and a differentiator 610 are coupled in parallel with the integrator 604 between the input and output variable gain stages 602, 606, as shown. In some examples, the front-end gain, the proportional gain of the proportional gain stage 608, a gain of the differentiator 610, and the output gain are all set/adjusted by control signals received via the digital programming interface 218. Similarly, a gain in the path of the integrator 604 can be controlled via the digital programming interface 218. Outputs from each of the proportional gain stage 608, the integrator 604, and the differentiator 610 are fed to a summer 612. The combined output from the summer 612 is provided at one input terminal of the output variable gain stage 606, as shown. The loop filter 518 receives at one input terminal of the input variable gain stage 602 a signal 614 that corresponds to the output from the low pass filter 516. The other input terminal of the input variable gain stage 602 is coupled to an adjustable offset DAC 616. In one example, the input variable gain stage is configured to apply a front-end gain to the input signal 614 in a range of between 0 dB and 10 dB.

The output signal from the input variable gain stage 602 is provided to each of the proportional gain stage 608, the integrator 604, and the differentiator 610. In one example, the proportional gain stage 608 is configured to apply a gain in a range of −21 dB to 21 dB. The integrator 604 and the differentiator 610 may each be individually enabled or disabled through a respective integration enable switch 618 and a differentiation enable switch 620. The enable switches 618, 620 can be controlled via the digital programming interface 218. Thus, depending on the configuration of the loop filter, the path between the output of the input variable gain stage 602 and the summer 612 may include the proportional gain stage 608 and one, both, or neither of the integrator 604 and/or the differentiator 610. In some examples, monitoring (using the differentiator 610) the derivative of the photodetector 504 with respect to detuning may allow the sign of the feedback signal 520 to be correctly determined on both sides of resonance.

In some examples, the integration path includes a secondary integrator 622 coupled in series with the integrator 604, as shown in FIG. 6. In one example, the integrator 604 is a relatively fast integrator, and the optional secondary integrator 622 may be a relatively slow integrator. The optional secondary integrator 622 may be used to boost the gain at DC for improved overall control of the frequency tuning. Both integrators 604, 622 include an integration hold switch 624. The integration hold switches (and therefore the integration hold time) can be controlled via the digital programming interface 218. The speed of the integrators may be controlled through selection of the associated passive components (e.g., resistors and/or capacitors used in the integration loops) and the time that the integration hold switches remain closed/open. In one example, the integration path further includes a unity gain buffer, as shown in FIG. 6. The integrators 604, 622 can be enabled/disabled via control signals received via the digital programming interface 218.

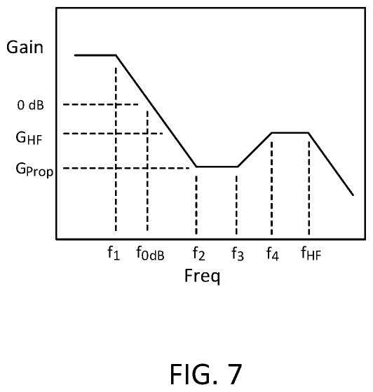

The output variable gain stage 606 outputs the electronic feedback/error signal 520. In some examples, the output variable gain stage 606 can be controlled to provide the output gain in a range of +6 dB to −50 dB, with the gain value being set via the digital programming interface 218, as described above. The output variable gain stage 606 has one input terminal coupled to the summer 612 and another input terminal coupled to an adjustable offset DAC 628. The adjustable offset DACs 616 and 628 may be used to control the gain provided by the corresponding input and output variable gain stages 602, 606, respectively. The offset values can be controlled by control signals received via the digital programming interface 218. The transfer function of the loop filter 518 may be controlled through selection of the values of the passive components (e.g., resistors and/or capacitors) associated with the integrators(s) 604, 622, the proportional gain stage 608, and/or the differential 610 and parameters set via the digital programming interface 218, as described above. An example of a loop filter transfer function is shown in FIG. 7. Table 1 below provides an example of values for the loop filter 518 corresponding to the transfer function shown in FIG. 7.

TABLE 1

| | Nominal Value | | Total Range |
|---|---|---|---|
| Slow Integrator 622, F_{0 dB} | 1 | kHz | 200 Hz-37 KHz |
| Fast Integrator 604, F_{0 dB} | 10 | kHz | 530 Hz-220 kHz |
| F₂ | 200 | kHz | 1 kHz-700 kHz |
| F₃ | 1 | MHz | 53 kHz-1.8 MHz, Off |
| F₄ | 3 | MHz | 1 MHz-40 MHz |
| Gproportional | | | −21-21 dB |
| G_{HF} | | | −21-24 dB |

As described above, temperature can affect the operating parameters and performance of the laser diode 202, and therefore, the laser control system may include circuitry and components to provide temperature stabilization and tuning. For example, temperature control of the PIC 230 and the micro-resonator 208 may be used to achieve frequency stability in the clock signal 206. Temperature adjustment of the micro-resonator 208 can also be used as part of the laser frequency tuning process discussed above. Accordingly, as described above, in certain examples, the laser controller IC 300 includes thermal management circuitry 306 that is communicatively coupled to external thermal control circuitry 308. This circuitry, programmed via the digital programming interface 218, can be used to control the temperature of the laser diode 202 and/or the PIC 230 (or any of its components).

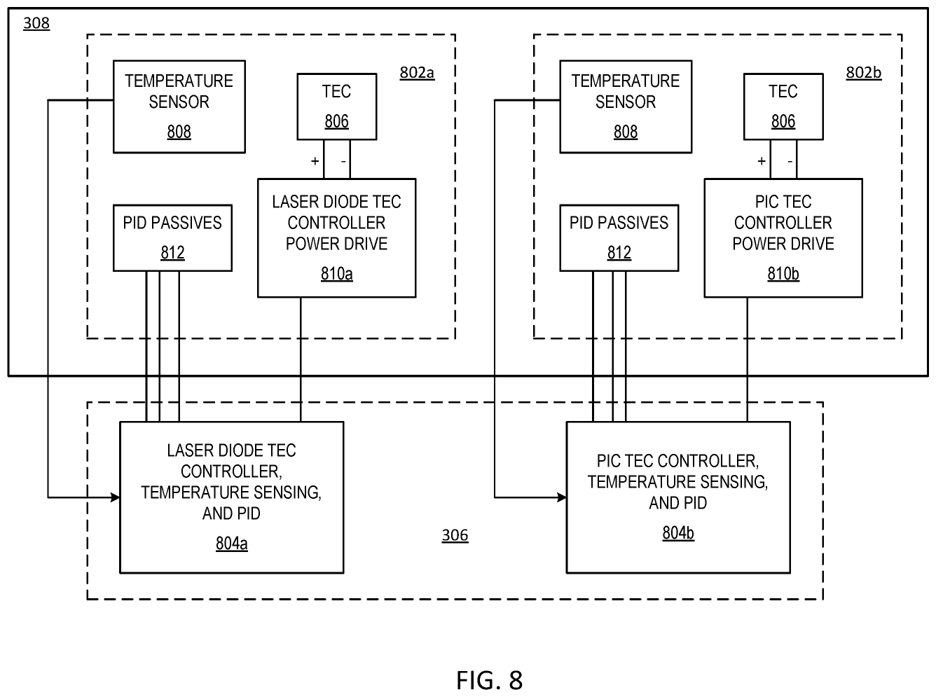

Referring to FIG. 8, there is illustrated an example of a certain components of the thermal management circuitry 306 and the external thermal control circuitry 308, according to some embodiments. In this example, the external thermal control circuitry 308 includes a first thermal control module 802a associated with the laser diode 202 and a second thermal control module 802b associated with the PIC 230. The two thermal control modules 802a, 802b may be referred to herein collectively as thermal control module(s) 802. The thermal management circuitry 306 includes a corresponding first thermal management module 804a coupled to the first thermal control module 802a and a second thermal management module 804b coupled to the second thermal control module 802b. In other examples, the external thermal control circuitry 308 may include one or more additional thermal control modules 802, and the thermal management circuitry 306 may include one or more corresponding additional thermal management modules 804. In some examples, the thermal management circuitry 306 includes at least one auxiliary thermal management module 804 to accommodate different laser diode 202 and/or PIC 230 configurations that may require additional thermal control.

According to certain examples, temperature control is provided using TECs and a feedback loop with a proportional-integral-derivative (PID) controller. Accordingly, the thermal control modules 802 may each include a TEC 806 and a temperature sensor 808. In one example, the temperature sensors 808 are thermistors, such as the thermistor 410 discussed above. Using the Pelletier effect, the TEC 806 heats or cools depending on the polarity of the current through the TEC. The amount of current may depend on the thermal load and the temperature difference between a selected set point temperature and the ambient temperature (e.g., the temperature of a heat sink coupled to the device (e.g., the laser diode 202 or the PIC 230) being thermally controlled. In certain examples, the drive current supplied to the TEC 806 can be in a range of 1-3 Amps. Since such high current levels may be unsuitable for the laser controller 300, as described above, a TEC controller and power drive component, referred to herein as a TEC driver 810, for each of the laser diode 202 (TEC driver 810a) and the PIC 230 (TEC driver 810b) may be implemented off-chip in the external thermal control circuitry 308.

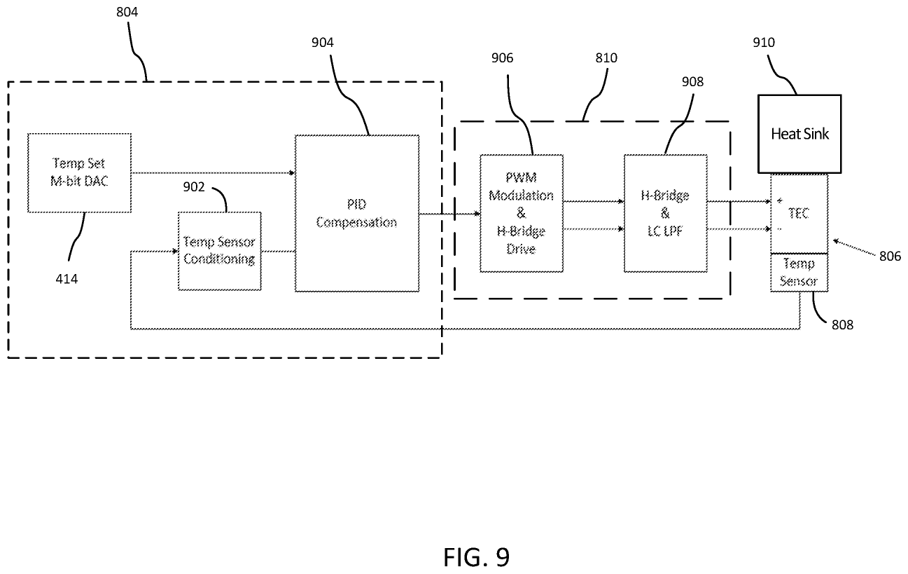

The thermal management modules 804 may be implemented in a variety of different ways. In some examples, a linear mode controller may be used, which may provide a relatively simple design, but may have low power efficiency (e.g., in a range of 10-20%). In some examples, a buck converter can be used to increase the power efficiency. In other examples, a switched mode H-bridge controller can be used, which may provide high power efficiency (e.g., ˜90%). FIG. 9 illustrates an example of a switched mode controller that may be used to implement the thermal management module 804 in some embodiments.

Referring to FIG. 9, in one example, the thermal management module 804 includes the temperature setpoint DAC 414 described above, temperature sensor conditioning circuitry 902, and a PID controller 904. The temperature setpoint DAC 414 can be controlled through a control signal received via the digital programming interface 218 to provide a specified temperature setpoint. The temperature sensor conditioning circuitry 902 is coupled to the temperature sensor 808. In the illustrated example, the TEC driver 810 includes a pulse width modulation (PWM) and H-bridge drive 906, along with an H-bridge and inductive-capacitive (LC) low pass filter (LPF) 908. A heat sink 910 is coupled to the TEC 806. The H-bridge and LC LPF 908 provides a positive or negative polarity drive current to the TEC 806 to cause the TEC 806 to heat or cool to drive the temperature of the associated device (e.g., the laser diode 202 or PIC 230) to a chosen setpoint. The temperature sensor 808 provides temperature feedback that is used by the PID controller to adjust the PWM and H-bridge drive 906 so as to alter the drive current supplied to the TEC 806 based on a measured delta between the chosen setpoint temperature and the ambient temperature of the heat sink 910.

As described above, in certain examples, temperature tuning is used to allow for scanning the laser frequency over specified range, which in some examples is up to twice the free spectral range. This tuning can be controlled using the temperature setpoint DAC 414 to drive the PID controller 904, which in turn drives the TEC driver 804. The temperature setpoint DAC 414 is an M-bit DAC, with the number of bits (M) being determined by the desired scan range and step precision. The free spectral range may be approximately 40-50 GHz in some examples. Thus, 2*50 GHz at a rate of 50 GHz per degree Celsius (C) results in a 2° C. temperature scan range. As also described above, in some examples, it is desirable to provide course frequency tuning to within 300 MHz of the nominal resonance of the micro-resonator, F₀. Assuming a tuning goal of 100 MHz from F₀, and the tuning rate of 50 GHZ/° C., this equates to 100 MHZ/50 GHZ/° C.=2 milliKelvin (mK) precision. Thus, a 2° C. (or 2K) temperature scan range with 2 mK step precision=2K/2 mK=1000, which equates to 10 bits for the temperature setpoint DAC 414.

However, the ambient temperature may also vary over a range of temperatures, depending on the environment in which the laser system 100 is operated. Accordingly, the thermal management module 804 may be configured to accommodate course temperature adjustment over a specified range of ambient temperatures as well. In one example, the specified ambient temperature is −40° C.-85° C. Allowing a 2.6 mK step precision for tuning over this specified ambient temperature range equates to ˜125/2.6=48, resulting in an additional 6 bits for the temperature setpoint DAC 414. Thus, in one example, the temperature setpoint DAC 414 is a 16-bit DAC. However, in other examples M may be a different number, depending on the temperature and frequency ranges to be scanned, the desired precision, and/or the scan rate.

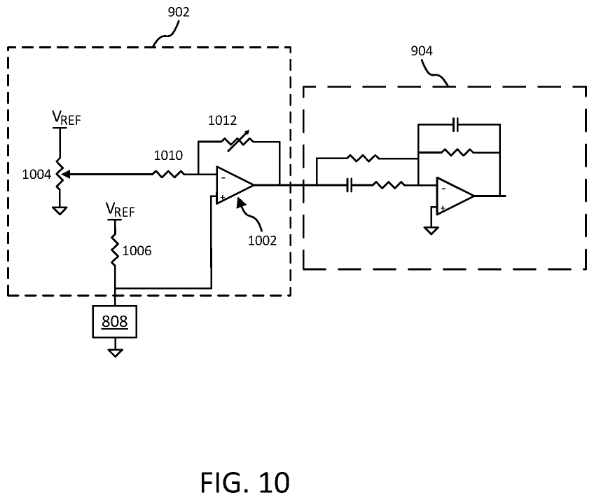

FIG. 10 illustrates a portion of one example of the thermal management module 804, including an example of the temperature sensor conditioning circuitry 902 and the PID controller 904. In this example, the temperature sensor conditioning circuitry 902 includes an amplifier 1002 and a pair of setpoint resistors 1004, 1006, each of which is coupled to a reference voltage terminal at which a reference voltage, Vref, is applied. The amplifier 1002 is configured (in part through selection of the values of resistors 1010, 1012) to set a maximum gain for twice the free spectral range. In some examples, the gain of the amplifier 1002 is set by a control signal received via the digital programming interface 218. In some examples, the gain of the amplifier 1002 can be tuned by adjusting the variable resistor 1012, which may be controlled via the digital programming interface 218. The resistor 1004 provides an ambient temperature range setting, and the resistor 1006 sets a low temperature cutoff to minimized setpoint drift with ambient temperature. The PID controller 904 may provide a filtering stage to stabilize the control loop response.

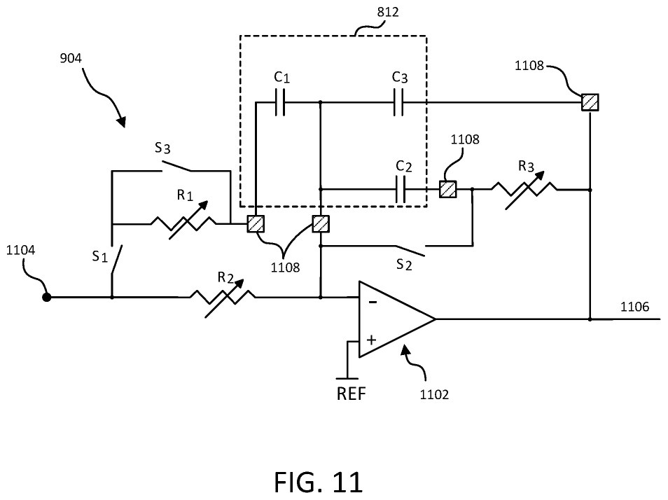

FIG. 11 illustrates an example of the PID controller 904. The PID controller 904 includes an amplifier 1102 having one input terminal coupled to a terminal 1104 that connects to the temperature sensor conditioning circuitry 902 and another input terminal coupled to a reference terminal, REF, at which the setpoint signal from the temperature setpoint DAC 414 is received. The PID controller 904 produces a control output signal 1106 that is fed to the TEC driver 810, as shown in FIG. 9. The PID controller 904 further includes a plurality of adjustable resistors R1, R2, and R3, along with capacitors C1, C2, and C3. In one example, the provision of four connection pads 1108 allows the adjustable resistors R1, R2, R3 to be implemented on-chip in the laser controller IC 300, while the capacitors C1, C2, C3 may be implemented off-chip, for example in the PID passives block 812 shown in FIG. 8. This may be advantageous as the capacitors C1, C2, C3 may be large, thus occupying significant die area, and/or may have high associated transients and/or noise. The resistance values of the adjustable resistors R1, R2, R3 may be controlled via DACS (not shown), such as 4-bit DACS, for example, that can be programmed via the digital programming interface 218. In some examples, external resistors may be added in the PID passives block 812 to extend the range of the on-chip resistor values.

According to certain examples, the values of the resistors R1, R2, and R3, and the capacitors C1, C2, C3, are selected based on a desired transfer function associated with the PID controller 904. For example, considering the transfer function shown in FIG. 7, the following set of equations provide the resistor and capacitor values corresponding to the frequency and gain points illustrated in FIG. 7.

$${f}_{0 dB} = \frac{1}{2 π {R}_{2} {C}_{2}}$$

$${f}_{2} = \frac{1}{2 π {R}_{3} {C}_{2}}$$

$${f}_{3} = \frac{1}{2 π {C}_{1} ( {R}_{1} + {R}_{2} )}$$

$${f}_{4} = \frac{1}{2 π {R}_{1} {C}_{1}}$$

$${f}_{HF} = \frac{1}{2 π {C}_{3} {R}_{3}}$$

$${G}_{prop} = \frac{{R}_{3}}{{R}_{2}}$$

$${G}_{HF} = \frac{{R}_{3}}{{R}_{1} ‖ {R}_{2}}$$

Still referring to FIG. 11, in some examples, programmable configuration switches S1, S2, and S3 provide for tuning, as well as an override option. For example, Opening S1 and closing S2 configures the PID controller for proportional gain only. Closing S2 eliminates the integration function, and opening S1 eliminates the differentiation function. Closing S3 may allow for a full R1 external override. In one example, including a “zero” Ohm (short circuit) option in the resistor DAC controlling R1 eliminates the need for S1. The switches S1, S2, S3 may be controlled via the digital programming interface 218.

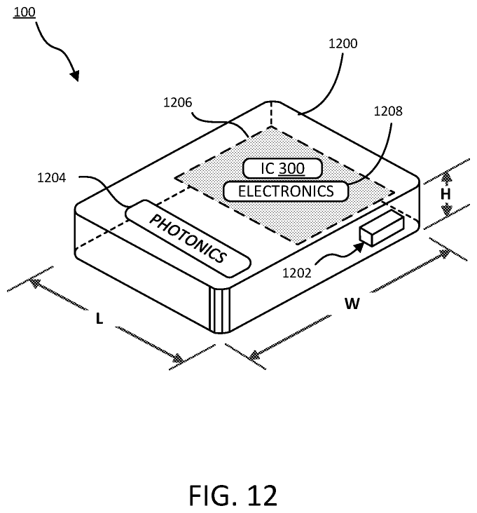

Thus, aspects and embodiments provide a fully configurable and programmable laser control and driver system that can be implemented in a small form factor. For example, referring to FIG. 12, there is illustrated an example of the laser system 100 packaged in a housing 1200. The housing may include a connector 1202 to allow for power and/or control signals (e.g., the configuration signals 224) to be provided to the laser system 100 and for various signals to be read out from the laser system 100. The housing 1200 may further include various other input/output connectors (not shown in FIG. 12) to allow for signals to be provided to (e.g., the input signal 114) and output from (e.g., the clock signal 206 or output laser beam 116) the laser system 100. The housing 1200 has a length, L, a width, W, and a height, H. In some examples, the height, H, is a range of 5 mm to 10 mm, the length, L, is in a range of 20 mm to 50 mm, and the width, W, is in a range of 20 mm to 50 mm. In some examples, the height, H, is in a range of 7 mm to 8 mm, the length, L, is in a range of 35 mm to 45 mm, and the width, W, is in the range of 25 mm to 35 mm. In further examples, the height, H, is in a range of 7.5 mm to 7.7 mm, the length, L, is in a range of 39 mm to 41 mm, and the width, W, is in a range of 29 mm to 31 mm.

The housing 1200 may contain photonic circuitry 1204, which may include the laser diode 202 and PIC 230, for example. The housing 1200 may further contain one or more package(s)/substrate(s) 1206, such as one or more printed circuit board(s) on which the laser controller IC 300 and other electronics 1208 (e.g., the thermal control circuitry 308 and laser bias circuitry 302) can be populated. The package(s) 1206 may be implemented using any type of three-dimensional heterogenous packaging. In some examples, the package(s) 1206 includes one or more glass or semi-conductor substrate(s), or wafer-level package(s). In some examples, the package(s) 1206 may have a total area of less than 20 mm×25 mm, for example, approximately 16 mm (+/−1 mm)×22 mm (+/−1 mm). By partitioning certain high power and/or high noise components, such as the high-current TEC drivers, power transistors (e.g., in the laser diode bias circuitry), and large capacitors, into separate packages, a small, low power laser controller IC 300 can be implemented providing a complete control solution for the laser system, as described above. In some examples, the laser controller IC 300 has a size of approximately 5 mm×5 mm (+/−1 mm in each dimension). Using digital control loops, high precision frequency and temperature tuning can be achieved over a wide frequency scan range. Further, using digital control allows operating parameters, tuning ranges, and component values to be fully programmable through a digital interface, as described above.

### Further Example Embodiments

The following examples pertain to further embodiments, from which numerous permutations and configurations will be apparent.

Example 1 provides a laser controller integrated circuit (IC) comprising a first input port, a second input port, and a sideband direct digital synthesizer (DDS) coupled to the first input port and configured to produce a modulation signal and a reference signal based on an input signal received via the first input port, the modulation signal and the reference signal having a same frequency. The laser controller further comprises a Pound-Drever-Hall (PDH) frequency-locking control loop coupled to the second input port and the sideband DDS, and configured to produce a corrected DC bias current signal based on the reference signal and a measurement signal received via the second input port, and a thermal management circuit configured to produce at least one thermal control signal.

Example 2 includes the laser controller IC of Example 1, further comprising a digital programming interface coupled to the sideband DDS, the PDH frequency-locking control loop, and the thermal management circuit, wherein the digital programming interface comprises one or more configuration registers coupled to a serial configuration interface.

Example 3 includes the laser controller IC of Example 2, wherein the PDH frequency-locking control loop is configurable based on control signals received via the digital programming interface.

Example 4 includes the laser controller IC of one of Examples 2 or 3, wherein the thermal management circuit is configurable based on control signals received via the digital programming interface.

Example 5 includes the laser controller IC of any one of Examples 1-4, wherein the measurement signal is sampled from a laser signal output by a laser diode and is representative of at least one sideband of the laser signal, wherein the modulation signal controls a sideband modulation of the laser signal, and wherein the reference signal is in phase with the sideband modulation of the laser signal.

Example 6 includes the laser controller IC of Example 5, further comprising a current summer, and wherein the PDH frequency-locking control loop comprises a transimpedance amplifier configured to convert the measurement signal to a voltage signal, a mixer coupled to an output of the transimpedance amplifier and configured to mix the voltage signal with the reference signal to produce a loop signal, and a loop filter coupled to the mixer and configured to produce an error signal based on the loop signal. The current summer is configured to produce the corrected DC bias current signal based on a nominal bias current signal, the modulation signal, and the error signal.

Example 7 includes the laser controller IC of Example 6, wherein the loop filter is a proportional-integral-derivative filter.

Example 8 includes the laser controller IC of Example 7, wherein the loop filter comprises a filter input terminal, a filter output terminal, a summer coupled to the filter output terminal, a proportional gain stage, an integrator coupled in parallel with the proportional gain stage between the filter input terminal and the summer, and a differentiator coupled in parallel with the proportional gain stage and the integrator between the filter input terminal and the summer.

Example 9 includes the laser controller IC of Example 8, wherein the integrator is a first integrator, and wherein the loop filter further comprises a second integrator coupled in series with the first integrator between the filter input terminal and the current summer.

Example 10 includes the laser controller IC of any one of Examples 1-9, further comprising a digital current controller coupled to the thermal management circuit and configured to sweep the DC bias current signal over a predetermined current range.

Example 11 includes the laser controller IC of Example 10, wherein the digital current controller comprises at least one digital-to-analog converter.

Example 12 includes the laser controller IC of one of Examples 10 or 11, wherein the thermal management circuit comprises a temperature setpoint digital-to-analog converter (DAC), and a proportional-integral-derivative (PID) controller.

Example 13 includes the laser controller IC of Example 12, wherein the temperature setpoint DAC is an M-bit DAC, wherein the thermal management circuit is configured to produce an adjustable thermal drive signal, and wherein M is selected based on an adjustment range of the thermal drive signal and an adjustment precision of the thermal driver signal.

Example 14 includes the laser controller IC of any one of Examples 1-13, further comprising a third input port, and a relative intensity noise suppression circuit coupled to the third input port.

Example 15 includes the laser controller IC of Example 14, wherein the second input port comprises a first photodiode, and wherein the third input port comprises a second photodiode.

Example 16 provides a housing containing a substrate, the substrate having the laser controller integrated circuit of any one of Examples 1-15 populated thereon, wherein the housing has a height, length, and width, the height being in the range of 5 mm to 20 mm, the length being in the range of 20 mm to 50 mm, and the width being in the range of 20 mm to 50 mm.

Example 17 includes the housing of Example 16, wherein the height is in the range of 7 mm to 8 mm, the length is in the range of 35 mm to 45 mm, and the width is in the range of 25 mm to 35 mm.

Example 18 includes the housing of Example 17, wherein the height is in the range of 7.5 mm to 7.7 mm, the length is in the range of 39 mm to 41 mm, and the width is in the range of 29 mm to 31 mm.

Example 19 provides a housing containing a substrate, the substrate having the laser controller integrated circuit of any one of Examples 1-15 populated thereon, wherein the housing has a height, length, and width, and wherein a sum of the height, the length, and the width is less than 120 mm.

Example 20 provides a housing containing a substrate, the substrate having the laser controller integrated circuit of any one of Examples 1-15 populated thereon, wherein the housing has a height, length, and width, the height being less than 20 mm, the length being less than 50 mm, and the width being less than 50 mm.

Example 21 includes the housing of any one of Examples 16-20, wherein the substrate includes at least one of a printed circuit board (PCB), a wafer-level package, a glass substrate, a semiconductor substrate, or any type of three-dimensional heterogenous packaging.

Example 22 provides a laser controller comprising laser bias current circuitry, thermal control circuitry, and the laser controller IC of any one of Examples 1-15.

Example 23 provides a laser controller comprising laser bias current circuitry, thermal control circuitry, and a laser controller integrated circuit (IC). The laser controller IC includes a digital programming interface, a first input port, a second input port, and a sideband direct digital synthesizer coupled to the first input port and configured to produce a reference signal based on an input signal received via the first input port and one or more first control signals received via the digital programming interface. The laser controller IC further includes a Pound-Drever-Hall (PDH) frequency-locking control loop coupled to the second input port, to the sideband direct digital synthesizer, to the digital programming interface, and to the laser bias current circuitry, the PDH frequency-locking loop configured to produce a corrected DC bias current signal based on the reference signal, one or more second control signals received via the digital programming interface, and a measurement signal received via the second input port, and to provide the corrected DC bias current signal to the laser bias current circuitry. The laser controller IC further includes a thermal management circuit coupled to the digital programming interface and to the thermal control circuitry, the thermal management circuit configured to provide at least one thermal control signal to the thermal control circuitry based on one or more thermal control signals received via the digital programming interface.

Example 24 includes the laser controller of Example 23, wherein the digital programming interface comprises one or more configuration registers coupled to an I2C serial configuration interface.

Example 25 includes the laser controller of one of Examples 23 or 24, wherein the measurement signal represents at least one sideband of a laser signal output from a laser diode, wherein the reference signal is in phase with a sideband modulation of the laser signal, and wherein the sideband direct digital synthesizer is further configured to produce a modulation signal that controls the sideband modulation of the laser signal, the modulation signal and the reference signal having a same frequency.

Example 26 includes the laser controller of Example 25, further comprising a current summer, and wherein the PDH frequency-locking control loop comprises a transimpedance amplifier configured to convert the measurement signal to a voltage signal, a mixer coupled to an output of the transimpedance amplifier and configured to mix the voltage signal with the reference signal to produce a loop signal, and a loop filter coupled to the mixer and configured to produce an error signal based on the loop signal. The current summer is configured to produce the corrected DC bias current signal based on a nominal bias current signal, the modulation signal, and the error signal.

Example 27 includes the laser controller of Example 26, wherein the loop filter is a proportional-integral-derivative filter.

Example 28 includes the laser controller of Example 27, wherein the loop filter comprises a filter input terminal, a filter output terminal, a summer coupled to the filter output terminal, a proportional gain stage coupled between the filter input terminal and the summer, an integrator coupled in parallel with the proportional gain stage between the filter input terminal and the summer, and a differentiator coupled in parallel with the proportional gain stage and the integrator between the filter input terminal and the summer.

Example 29 includes the laser controller of Example 28, wherein the integrator is a first integrator, and wherein the loop filter further comprises a second integrator coupled in series with the first integrator between the filter input terminal and the summer.

Example 30 includes the laser controller of any one of Examples 23-29, wherein the thermal control circuitry comprises at least one thermoelectric cooler (TEC), at least one TEC driver coupled to the at least one TEC and configured to provide a drive current to the at least one TEC, the drive current being based on the at least one thermal control signal, and a temperature sensor coupled to the at least one TEC and configured to provide a sensor signal representative of a temperature of a controlled device.

Example 31 includes the laser controller of Example 30, wherein the controlled device is a laser diode.

Example 32 includes the laser controller of Example 30, wherein the controlled device is a photonic integrated circuit.

Example, 33 includes the laser controller of any one of Examples 30-32, wherein the thermal management circuit comprises a temperature setpoint digital-to-analog converter (DAC) configured to provide a thermal setpoint signal based on the one or more thermal control signals received via the digital programming interface, and a proportional-integral-derivative (PID) controller configured to produce the least one thermal control signal based on the sensor signal and the thermal setpoint signal.

Example 34 includes the laser controller of Example 33, wherein the temperature setpoint DAC is an M-bit DAC, and wherein M is selected based on a temperature control range of the at least one TEC and predetermined adjustment precision within the temperature control range.

Example 35 includes the laser controller of one of Examples 33 or 34, further comprising one or more passive electronic devices coupled to the thermal management circuit.

Example 36 includes the laser controller of Example 35, wherein the one or more passive electronic devices include a plurality of capacitors coupled to the PID controller.

Example 37 includes the laser controller of any one of Examples 30-36, wherein the thermal management circuit further comprises temperature sensor conditioning circuitry coupled to the temperature sensor and configured to condition the sensor signal.

Example 38 includes the laser controller of any one of Examples 30-37, further comprising a digital current controller coupled to the thermal management circuit and configured to sweep the DC bias current signal over a predetermined current range.

Example 39 includes the laser controller of Example 38, wherein the digital current controller comprises at least one digital-to-analog converter.

Example 40 includes the laser controller of any one of Examples 23-39, further comprising a third input port, and a relative intensity noise suppression circuit coupled to the third input port.

Example 41 includes the laser controller of Example 40, wherein the second input port comprises a first photodiode, and wherein the third input port comprises a second photodiode.

Example 42 provides a printed circuit board comprising the laser controller of any one of Examples 23-41.

Example 43 provides a three-dimensional heterogenous package comprising the laser controller of any one of Examples 23-41.

Example 44 provides a laser system comprising a laser diode configured to produce a laser signal, and a photonic integrated circuit coupled to the laser diode and comprising a micro-resonator, and a phase modulator configured to modulate the laser signal to produce a clock signal. The laser system further comprises a laser controller integrated circuit (IC) comprising a digital programming interface, a first input port, a second input port, and a sideband direct digital synthesizer (DDS) coupled to the first input port and configured to receive an input signal via the first input port and to produce a reference signal based on the reference signal. The laser controller IC further comprises a Pound-Drever-Hall (PDH) frequency-locking control loop coupled to the second input port, to the sideband direct digital synthesizer, and to the digital programming interface, the PDH frequency-locking control loop configured to receive, via the second input port, a sample of the clock signal, and to produce, based on the reference signal and the sample of the clock signal, a corrected DC bias current signal for the laser diode to lock a frequency of the laser signal to a resonance frequency of the micro-resonator, and a thermal management circuit coupled to the digital programming interface and configured to produce, based on one or more first control signals received via the digital programming interface, at least one thermal control signal to tune a temperature of at least one of the laser diode or the photonic integrated circuit.

Example 45 includes the laser system of Example 44, wherein the photonic integrated circuit further comprises at least one thermoelectric cooler (TEC), and wherein the laser system further comprises a temperature sensor configured to provide a sensor signal representative of the temperature of at least one of the laser diode or the photonic circuit, and at least one TEC driver coupled to the at least one TEC and configured to provide a drive current to the at least one TEC to tune the temperature of at least one of the laser diode or the photonic integrated circuit.

Example 46 includes the laser system of one of Examples 44 or 45, wherein the thermal management circuit comprises a temperature setpoint digital-to-analog converter (DAC) configured to provide a thermal setpoint signal, and a proportional-integral-derivative (PID) controller configured to produce the least one thermal control signal based on the sensor signal and the thermal setpoint signal.

Example 47 includes the laser system of Example 46, wherein the thermal management circuit is configured to adjust the at least one thermal control signal to tune the temperature of the laser diode so as to scan the laser signal over a predetermined frequency range.

Example 48 includes the laser system of Example 47, wherein the predetermined frequency range corresponds to twice a free spectral range of the micro-resonator.

Example 49 includes the laser system of any one of Examples 44-48, wherein the laser controller IC further comprises a digital current controller configured to sweep a DC bias current of the laser diode over a predetermined current range so as to scan the laser signal over a predetermined frequency range to locate the resonance frequency of the micro-resonator.

Example 50 includes the laser system of Example 49, wherein the digital current controller is coupled to the digital programming interface, and wherein the predetermined current range is set by a second control signal received via the digital programming interface.

Example 51 includes the laser system of any one of Examples 44-50, wherein the sideband DDS is coupled to the digital programming interface and further configured to produce, based on the input signal and a DDS control signal received via the digital programming interface, a modulation signal to control sideband modulation of the laser signal, wherein the modulation signal and the reference signal have a same frequency.

Example 52 includes the laser system of any one of Examples 44-51, wherein the PDH frequency-locking control loop is configurable based on one or more second control signals received via the digital programming interface.

Example 53 includes the laser system of Example 52, wherein the PDH frequency-locking loop comprises a transimpedance amplifier configured to convert the sample of the clock signal to a voltage signal, a mixer coupled to an output of the transimpedance amplifier and configured to mix the voltage signal with the reference signal to produce a loop signal, and a loop filter coupled to the mixer and configured to produce an error signal based on the loop signal.

Example 54 includes the laser system of Example 53, further comprising a current summer coupled to an output of the loop filter of the PDH frequency-locking control loop, the current summer being configured to produce the corrected DC bias current signal based on a nominal bias current signal, the modulation signal, and the error signal.

Example 55 includes the laser system of one of Examples 53 or 54, wherein the loop filter is a proportional-integral-derivative filter.

Example 56 includes the laser system of any one of Examples 53-55, wherein the loop filter comprises a filter input terminal, a filter output terminal, a summer coupled to the filter output terminal, a proportional gain stage coupled between the filter input terminal and the summer, an integrator coupled in parallel with the proportional gain stage between the filter input terminal and the current summer; and a differentiator coupled in parallel with the proportional gain stage and the integrator between the filter input terminal and the summer.

Example 57 includes the laser system of Example 56, wherein the integrator is a first integrator, and wherein the loop filter further comprises a second integrator coupled in series with the first integrator between the filter input terminal and the current summer.

Example 58 includes the laser system of any one of Examples 44-57, further comprising a housing containing a package, the package having the laser controller IC populated thereon, wherein the housing has a height, length, and width, the height being in the range of 5 mm to 20 mm, the length being in the range of 20 mm to 50 mm, and the width being in the range of 20 mm to 50 mm, the housing further containing the laser diode and the photonic integrated circuit.

Example 59 includes the laser system of Example 58, wherein the height is in the range of 7 mm to 8 mm, the length is in the range of 35 mm to 45 mm, and the width is in the range of 25 mm to 35 mm.

Example 60 includes the laser system of Example 59, wherein the height is in the range of 7.5 mm to 7.7 mm, the length is in the range of 39 mm to 41 mm, and the width is in the range of 29 mm to 31 mm.

Example 61 includes the laser system of any one of Examples 44-57, further comprising a housing containing a package, the package having the laser controller IC populated thereon, wherein the housing has a height, length, and width, and wherein a sum of the height, the length, and the width is less than 120 mm.

Example 62 includes the laser system of any one of Examples 44-57, further comprising a housing containing a package, the package having the laser controller IC populated thereon, wherein the housing has a height, length, and width, the height being less than 20 mm, the length being less than 50 mm, and the width being less than 50 mm.

Example 63 includes the laser system of any one of Examples 58-62, wherein the package includes any type of three-dimensional heterogenous packaging.

Example 64 includes the laser system of any one of Examples 58-62, wherein the package includes at least one of a printed circuit board, a glass substrate, or a semiconductor substrate.

Example 65 includes the laser system of any one of Examples 61-64, wherein the laser diode and the photonic integrated circuit are disposed within the housing.

The terms and expressions which have been employed herein are used as terms of description and not of limitation, and there is no intention, in the use of such terms and expressions, of excluding any equivalents of the features shown and described (or portions thereof), and it is recognized that various modifications are possible within the scope of the claims. Accordingly, the claims are intended to cover all such equivalents. Various features, aspects, and embodiments have been described herein. The features, aspects, and embodiments are susceptible to combination with one another as well as to variation and modification, as will be appreciated in light of this disclosure. The present disclosure should, therefore, be considered to encompass such combinations, variations, and modifications. It is intended that the scope of the present disclosure be limited not by this detailed description, but rather by the claims appended hereto. Future filed applications claiming priority to this application may claim the disclosed subject matter in a different manner and may generally include any set of one or more elements as variously disclosed or otherwise demonstrated herein.

What is claimed is:

1. A laser controller integrated circuit comprising:
a first input port;
a second input port;
a sideband direct digital synthesizer (DDS) coupled to the first input port and configured to produce a modulation signal and a reference signal based on an input signal received via the first input port, the modulation signal and the reference signal having a same frequency;
a Pound-Drever-Hall (PDH) frequency-locking control loop coupled to the second input port and the DDS, and configured to produce a corrected DC bias current signal based on the reference signal and a measurement signal received via the second input port; and
a thermal management circuit configured to produce at least one thermal control signal.

2. The laser controller integrated circuit of claim 1, further comprising a digital programming interface coupled to the sideband DDS, the PDH frequency-locking control loop, and the thermal management circuit, wherein the digital programming interface comprises one or more configuration registers coupled to a serial configuration interface.

3. The laser controller integrated circuit of claim 1, wherein the measurement signal is sampled from a laser signal output by a laser diode and is representative of at least one sideband of the laser signal, wherein the modulation signal controls a sideband modulation of the laser signal, and wherein the reference signal is in phase with the sideband modulation of the laser signal.

4. The laser controller integrated circuit of claim 3, further comprising a current summer; and wherein the PDH frequency-locking control loop comprises:
a transimpedance amplifier configured to convert the measurement signal to a voltage signal;
a mixer coupled to an output of the transimpedance amplifier and configured to mix the voltage signal with the reference signal to produce a loop signal; and
a loop filter coupled to the mixer and configured to produce an error signal based on the loop signal;
wherein the current summer is configured to produce the corrected DC bias current signal based on a nominal bias current signal, the modulation signal, and the error signal.

5. The laser controller integrated circuit of claim 1, further comprising:
a digital current controller coupled to the thermal management circuit and configured to sweep the DC bias current signal over a predetermined current range.

6. The laser controller integrated circuit of claim 5, wherein the thermal management circuit comprises:
a temperature setpoint digital-to-analog converter (DAC); and
a proportional-integral-derivative (PID) controller.

7. The laser controller integrated circuit of claim 1, further comprising:
a third input port; and
a relative intensity noise suppression circuit coupled to the third input port.

8. A housing containing a substrate, the substrate having the laser controller integrated circuit of claim 1 populated thereon, wherein the housing has a height, length, and width, the height being in the range of 5 mm to 20 mm, the length being in the range of 20 mm to 50 mm, and the width being in the range of 20 mm to 50 mm.

9. A laser controller comprising:
laser bias current circuitry;
thermal control circuitry; and
a laser controller integrated circuit including
a digital programming interface,
a first input port,
a second input port,
a sideband direct digital synthesizer coupled to the first input port and configured to produce a reference signal based on an input signal received via the first input port and one or more first control signals received via the digital programming interface,
a Pound-Drever-Hall (PDH) frequency-locking control loop coupled to the second input port, to the sideband direct digital synthesizer, to the digital programming interface, and to the laser bias current circuitry, the PDH frequency-locking loop configured to produce a corrected DC bias current signal based on the reference signal, one or more second control signals received via the digital programming interface, and a measurement signal received via the second input port, and to provide the corrected DC bias current signal to the laser bias current circuitry, and
a thermal management circuit coupled to the digital programming interface and to the thermal control circuitry, the thermal management circuit configured to provide at least one thermal control signal to the thermal control circuitry based on one or more thermal control signals received via the digital programming interface.

10. The laser controller of claim 9, wherein the measurement signal represents at least one sideband of a laser signal output from a laser diode;
wherein the reference signal is in phase with a sideband modulation of the laser signal; and
wherein the sideband direct digital synthesizer is further configured to produce a modulation signal that controls the sideband modulation of the laser signal, the modulation signal and the reference signal having a same frequency.

11. The laser controller of claim 10, further comprising a current summer; and wherein the PDH frequency-locking control loop comprises:
a transimpedance amplifier configured to convert the measurement signal to a voltage signal;
a mixer coupled to an output of the transimpedance amplifier and configured to mix the voltage signal with the reference signal to produce a loop signal; and
a loop filter coupled to the mixer and configured to produce an error signal based on the loop signal;
wherein the current summer is configured to produce the corrected DC bias current signal based on a nominal bias current signal, the modulation signal, and the error signal.

12. The laser controller of claim 9, wherein the thermal control circuitry comprises:
at least one thermoelectric cooler (TEC);
at least one TEC driver coupled to the at least one TEC and configured to provide a drive current to the at least one TEC, the drive current being based on the at least one thermal control signal; and
a temperature sensor coupled to the at least one TEC and configured to provide a sensor signal representative of a temperature of a controlled device.

13. The laser controller of claim 12, wherein the thermal management circuit comprises:
a temperature setpoint digital-to-analog converter (DAC) configured to provide a thermal setpoint signal based on the one or more thermal control signals received via the digital programming interface; and
a proportional-integral-derivative (PID) controller configured to produce the least one thermal control signal based on the sensor signal and the thermal setpoint signal.

14. The laser controller of claim 13, wherein the thermal management circuit further comprises:
temperature sensor conditioning circuitry coupled to the temperature sensor and configured to condition the sensor signal.

15. The laser controller of claim 13, further comprising:
a digital current controller coupled to the thermal management circuit and configured to sweep the DC bias current signal over a predetermined current range.

16. A laser system comprising:
a laser diode configured to produce a laser signal;
a photonic integrated circuit coupled to the laser diode and comprising
a micro-resonator, and
a phase modulator configured to modulate the laser signal to produce a clock signal; and
a laser controller integrated circuit (IC) comprising
a digital programming interface,
a first input port,
a second input port,
a sideband direct digital synthesizer (DDS) coupled to the first input port and configured to receive an input signal via the first input port and to produce a reference signal based on the reference signal,
a Pound-Drever-Hall (PDH) frequency-locking control loop coupled to the second input port, to the sideband DDS, and to the digital programming interface, the PDH frequency-locking control loop configured to receive, via the second input port, a sample of the clock signal, and to produce, based on the reference signal and the sample of the clock signal, a corrected DC bias current signal for the laser diode to lock a frequency of the laser signal to a resonance frequency of the micro-resonator, and
a thermal management circuit coupled to the digital programming interface and configured to produce, based on one or more first control signals received via the digital programming interface, at least one thermal control signal to tune a temperature of at least one of the laser diode or the photonic integrated circuit.

17. The laser system of claim 16, wherein the photonic integrated circuit further comprises at least one thermoelectric cooler (TEC), the laser system further comprising:
a temperature sensor configured to provide a sensor signal representative of the temperature of at least one of the laser diode or the photonic circuit; and
at least one TEC driver coupled to the at least one TEC and configured to provide a drive current to the at least one TEC to tune the temperature of at least one of the laser diode or the photonic integrated circuit.

18. The laser system of claim 17, wherein the thermal management circuit comprises
a temperature setpoint digital-to-analog converter (DAC) configured to provide a thermal setpoint signal; and
a proportional-integral-derivative (PID) controller configured to produce the least one thermal control signal based on the sensor signal and the thermal setpoint signal.

19. The laser system of claim 18, wherein the thermal management circuit is configured to adjust the at least one thermal control signal to tune the temperature of the laser diode so as to scan the laser signal over a predetermined frequency range.

20. The laser system of claim 16, wherein the laser controller integrated circuit further comprises a digital current controller configured to sweep a DC bias current of the laser diode over a predetermined current range so as to scan the laser signal over a predetermined frequency range to locate the resonance frequency of the micro-resonator.
